(19) United States
(12) Patent Application Publication
(10) Pub. No.: US 2026/0123450 A1
(43) Pub. Date: Apr. 30, 2026

(54) ELECTRONIC DEVICE AND MANUFACTURING METHOD THEREOF

(71) Applicant: InnoLux Corporation, Miao-Li County (TW)

(72) Inventors: Hung-Cheng LIN, Miao-Li County (TW); Chao-Jen Chen, Miao-Li County (TW); Fu-Kuang Tseng, Miao-Li County (TW)

(73) Assignee: InnoLux Corporation, Miao-Li County (TW)

(21) Appl. No.: 19/326,719

(22) Filed: Sep. 11, 2025

Related U.S. Application Data
(60) Provisional application No. 63/713,600, filed on Oct. 30, 2024.

(30) Foreign Application Priority Data
Jun. 27, 2025 (CN) 202510872719.2

(51) Int. Cl. H01L 21/48; H01L 23/00; H01L 23/538; H01L 25/065

(52) U.S. Cl. CPC H10W 70/092; H10W 70/095; H10W 70/611; H10W 70/635; H10W 74/15; H10W 90/00; H10W 90/724; H10W 90/734

(57) ABSTRACT

An electronic device and a manufacturing method thereof are disclosed. The manufacturing method of the electronic device includes: providing a substrate; performing a hole-forming process on the substrate to form a through hole in the substrate; performing a first inspection step to the substrate to obtain a first inspection result; and determining whether a condition of the through hole is abnormal based on the first inspection result. A through hole rework process is performed on the substrate when the condition of the through hole is determined to be abnormal, and the through hole rework process includes performing a rework direction determining step to determine whether the substrate needs to be flipped during performing the through hole rework process.

### CROSS REFERENCE TO RELATED APPLICATION

This application claims the benefit of U.S. Provisional Application No. 63/713,600, filed on Oct. 30, 2024. The content of the application is incorporated herein by reference.

### BACKGROUND OF THE DISCLOSURE

### 1. FIELD OF THE DISCLOSURE

The present disclosure relates to an electronic device and a manufacturing method thereof, and more particularly to a manufacturing method of an electronic device including performing an inspection step to the substrate and an electronic device manufactured by the method.

### 2. DESCRIPTION OF THE PRIOR ART

In the existing electronic device, a through hole may be formed in the substrate, and a conductive material is disposed in the through hole to serve as a conducting wire for transmitting an electrical signal. However, as the size of the through hole becomes smaller and smaller, and the depth-width ratio and density thereof become higher and higher, the complexity of subsequent defect detection for through hole may be affected. In addition, the quality inspection for the through hole of the substrate is also a critical issue that requires further discussion.

### SUMMARY OF THE DISCLOSURE

One of objectives of the present disclosure is to provide a manufacturing method of an electronic device and an electronic device manufactured by the method, wherein by performing an inspection step during the manufacturing process to determine the condition of the through hole, and by reducing abnormalities through a through hole rework process, the production efficiency may be improved, and the yield and reliability of the electronic device may be improved.

An embodiment of the present disclosure provides a manufacturing method of an electronic device. The method includes: providing a substrate; performing a hole-forming process on the substrate to form a through hole in the substrate; performing a first inspection step to the substrate to obtain a first inspection result; and determining whether a condition of the through hole is abnormal based on the first inspection result. A through hole rework process is performed on the substrate when the condition of the through hole is determined to be abnormal, and the through hole rework process includes performing a rework direction determining step to determine whether the substrate needs to be flipped during performing the through hole rework process.

An embodiment of the present disclosure provides an electronic device. The electronic device includes a substrate, a conductive element, a circuit structure and an electronic unit. The substrate includes a through hole, and the conductive element is disposed in the through hole. The circuit structure is disposed on a side of the substrate. The electronic unit is disposed on the circuit structure and electrically connected to the conductive element through the circuit structure. The through hole has a top diameter and a bottom diameter, and a ratio of the top diameter to the bottom diameter is greater than or equal to 0.8 and less than or equal to 1.2 These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a flowchart of a manufacturing method of an electronic device according to an embodiment of the present disclosure.

FIG. 2A is a top-view schematic diagram illustrating a portion of the process of a manufacturing method of an electronic device according to an embodiment of the present disclosure.

FIG. 2B is a partial cross-sectional schematic diagram of a portion of the process of the electronic device shown in FIG. 2A.

FIG. 3 to FIG. 5 are schematic diagrams illustrating a portion of the process of a manufacturing method of an electronic device according to an embodiment of the present disclosure.

FIG. 6 to FIG. 9 are schematic diagrams illustrating a portion of the process of a manufacturing method of an electronic device according to an embodiment of the present disclosure.

FIG. 10 is a schematic diagram illustrating a portion of the process of a manufacturing method of an electronic device according to another embodiment of the present disclosure.

FIG. 11 is a cross-sectional schematic diagram of an electronic device according to an embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the device or structure, and certain components in various drawings may not be drawn to scale. In addition, the number and dimension of each component shown in drawings are only illustrative and are not intended to limit the scope of the present disclosure.

Certain terms are used throughout the description and following claims to refer to particular components. As one skilled in the art will understand, electronic equipment manufacturers may refer to a component by different names. The present disclosure does not intend to distinguish between components that differ in name but not function. In the following description and in the claims, the terms “include”, “comprise” and “have” are used in an open-ended fashion, and thus should be interpreted to mean “include, but not limited to . . . ”. When the terms “include”, “comprise” and/or “have” are used in the description of the present disclosure, the corresponding features, areas, steps, operations and/or components would be pointed to existence, but not limited to the existence or addition of one or a plurality of the corresponding or other features, areas, steps, operations, components and/or combinations thereof.

When an element or layer is referred to as being “on” or “connected to” another element or layer, it may be directly on or directly connected to the other element or layer, or intervening elements or layers may be presented (indirect condition). In contrast, when an element is referred to as being “directly on” or “directly connected to” another element or layer, there are no intervening elements or layers presented.

The directional terms mentioned in the present disclosure, such as “up”, “down”, “front”, “back”, “left”, “right”, “top”, “bottom”, etc., are only directions referring to the drawings. Therefore, the directional terms used are for illustration, not for limitation of the present disclosure.

The terms “about”, “equal”, “identical” or “the same”, and “substantially” or “approximately” mentioned in the present disclosure generally mean being within 20% of a given value or range, or being within 10%, 5%, 3%, 2%, 1% or 0.5% of a given value or range.

The term “between a value A and a value B” is interpreted as including the value A and the value B or including at least one of the value A and the value B, and including other values between the value A and the value B.

In the present disclosure, the depth, thickness, length, width, and/or hole diameter may be measured by using an X-ray diffractometer (XRD), an optical microscope (OM), an electron microscope (such as a scanning electron microscope (SEM), a transmission electron microscope (TEM), etc.) or other methods, but not limited herein.

In the present disclosure, the roughness may be determined by observing through a SEM. On an uneven surface, it may be seen that a height difference of 0.15 micrometers (μm) to 1 micrometer exists between the peaks and the valleys of the surface. The measurement of the roughness determination may include observing surface undulations using instruments such as a SEM, a TEM and the like at the same appropriate magnification, and taking a sample with a unit length (e.g., 10 μm) to compare the undulation condition as its roughness range. The term “appropriate magnification” described above refers to a magnification at which at least 10 undulating peaks of a roughness (Rz) or an average roughness (Ra) of at least one surface can be seen within the field of view.

The ordinal numbers used in the description and claims, such as “first”, “second”, “third”, etc., are used to describe elements, but they do not mean and represent that the element(s) have any previous ordinal numbers, nor do they represent the order of one element and another element, or the order of manufacturing methods. The ordinal numbers are used only to clearly discriminate an element with a certain name from another element with the same name. The claims and the description may not use the same terms. Accordingly, in the following description, a first constituent element may be a second constituent element in a claim.

The electronic device of the present disclosure may applied to a semiconductor package device, a display device, a light-emitting device, a backlight device, an antenna device, a sensing device, a tiled device or other suitable devices, but not limited herein. The display device may include a non-self-emissive display device or a self-emissive display device. The antenna device may include a liquid-crystal type antenna device or an antenna device other than liquid-crystal type, and the sensing device may include a sensing device used for sensing capacitance, light, heat or ultrasonic waves, but not limited herein. The electronic device may include electronic elements such as semiconductor elements. The semiconductor elements may include passive elements and active elements, such as capacitors, resistors, inductors, diodes, transistors, integrated circuits, etc. The diode may include a light emitting diode, a photodiode or a varicap diode. The light emitting diode may include, for example, an organic light emitting diode (OLED), a mini light emitting diode (mini LED), a micro light emitting diode (micro LED) or a quantum dot light emitting diode (quantum dot LED), but not limited herein. The semiconductor element may include a semiconductor layer or an electronic element manufactured by a semiconductor process, but not limited herein. The tiled device may be, for example, a display tiled device or an antenna tiled device, but not limited herein. The electronic device may include peripheral systems such as a driving system, a controlling system, a light source system, a shelving system, and the like. The outline of the electronic device may be a rectangle, a circle, a polygon, a shape with curved edge, curved or other suitable shapes. It should be noted that the electronic device of the present disclosure may be any combination of the above devices, but not limited herein.

The manufacturing method of the electronic device of the present disclosure may for example be applied to a wafer-level package (WLP) process or a panel-level package (PLP) process, wherein the WLP process or the PLP process may include a chip-first process or a chip-last process, but not limited herein. The electronic device may include the system on a chip (SoC), system in a package (SiP), antenna in package (AiP), co-packaged optics (CPO) or combinations of the above devices, but not limited herein.

It should be noted that the technical features in different embodiments described in the following can be replaced, recombined, or mixed with one another to constitute another embodiment without departing from the spirit of the present disclosure.

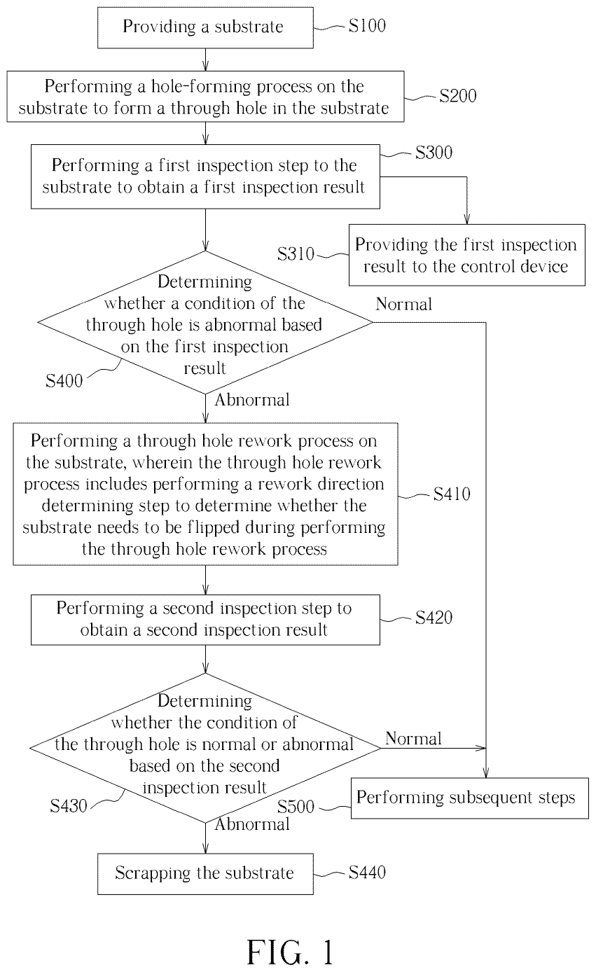

Please refer to FIG. 1, which is a flowchart of a manufacturing method of an electronic device according to an embodiment of the present disclosure. As shown in FIG. 1, a manufacturing method of an electronic device according to an embodiment of the present disclosure may include the following steps:

Step S100: providing a substrate.

Step S200: performing a hole-forming process on the substrate to form a through hole in the substrate.

Step S300: performing a first inspection step to the substrate to obtain a first inspection result.

Step S400: determining whether a condition of the through hole is abnormal based on the first inspection result, wherein Step S500 is performed when the condition of the through hole is determined to be normal, and Step S410 is performed when the condition of the through hole is determined to be abnormal.

Step S500: performing subsequent steps.

Step S410: performing a through hole rework process on the substrate, wherein the through hole rework process includes performing a rework direction determining step to determine whether the substrate needs to be flipped during performing the through hole rework process.

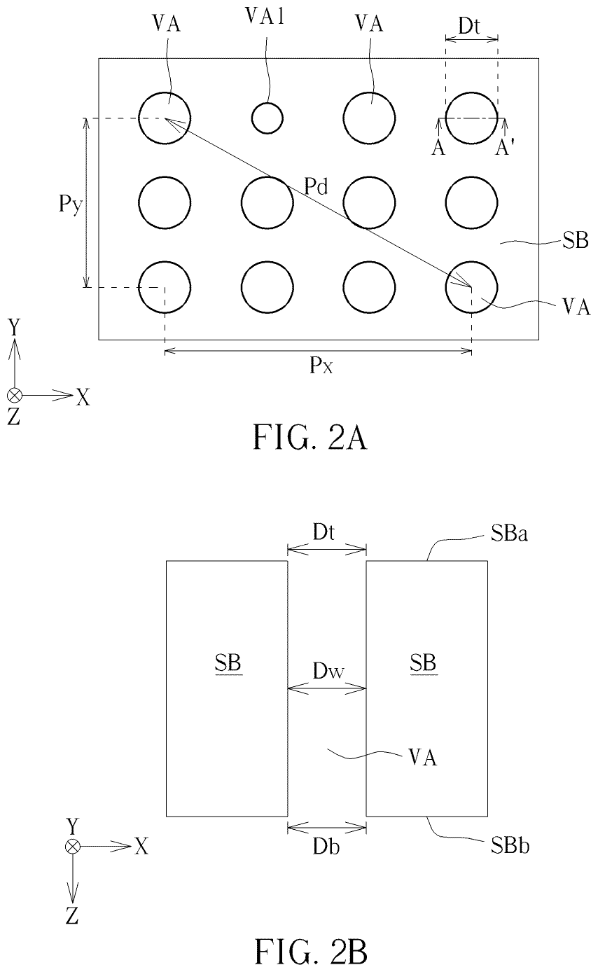

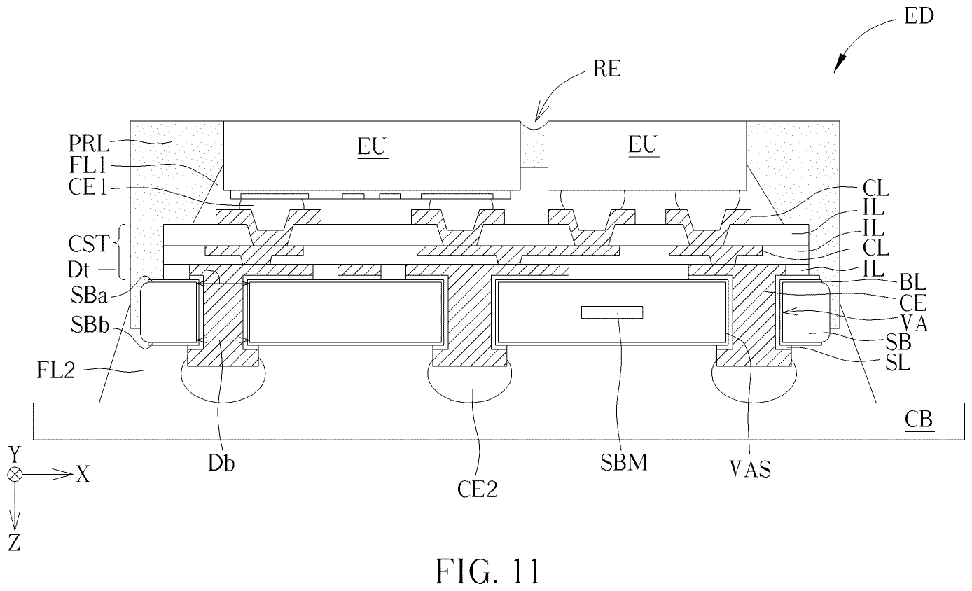

Specifically, according to Step S100, Step S200, and Step S300 of the manufacturing method of the electronic device of the present disclosure, please refer to FIG. 2A and FIG. 2B. FIG. 2A is a top-view schematic diagram illustrating a portion of the process of a manufacturing method of an electronic device according to an embodiment of the present disclosure. FIG. 2B is a partial cross-sectional schematic diagram of a portion of the process of the electronic device shown in FIG. 2A, wherein FIG. 2B may be a cross-sectional view corresponding to the section line A-A′ of FIG. 2A. As shown in FIG. 2A and FIG. 2B, and in conjunction with FIG. 1, first, Step S100 may be performed to provide a substrate SB. The substrate SB may include a glass substrate, a transparent material including silicon, an optical layer, an acrylic board, a semiconductor structure substrate, combinations of the above or other transparent materials, and the substrate SB may have certain stiffness and insulation. That is to say, the stiffness of the substrate SB may be greater than the stiffness of a circuit structure (such as the circuit structure CST shown in FIG. 11) formed on the substrate SB, for example, the stiffness of the substrate SB is greater than the stiffness of an insulating layer of the circuit structure, so that the warpage may be mitigated when the substrate SB is used for carrying the circuit structure, but not limited herein. The “stiffness” referred to in the present disclosure may be tested by a universal testing machine (UTM). In some embodiments, the thermal expansion coefficient of the substrate SB may be greater than or equal to 1 ppm/° C. and less than or equal to 10 ppm/° C., thereby improving the support of the substrate SB or further improving the reliability of the electronic device. In some embodiments, the transmittance of the substrate SB for visible light may be at least greater than or equal to 80%.

After Step S100, Step S200 may be performed to perform a hole-forming process on the substrate SB, so as to form one or more through holes VA in the substrate SB. The hole-forming process may include, for example, at least one of a photo-modification step, a light drilling step, a laser modification step, a laser drilling step and an etching step, to form one or more through holes VA penetrating through the substrate SB, wherein a side wall of the through hole VA is connected with an upper surface SBa and a lower surface SBb of the substrate SB. The laser drilling step may include using a laser beam to drill the substrate SB, and the etching step may include a dry etching process or a wet etching process, but not limited herein. After Step S200, Step S300 may be performed to perform a first inspection step to the substrate SB to obtain a first inspection result. The first inspection step may include optically inspecting the substrate SB by an optical system, for example (but not limited to) inspecting by an automated optical inspection (AOI) system. As shown in FIG. 2A and FIG. 2B, the first inspection result may include at least one of a position accuracy, a top diameter Dt, a waist diameter Dw, a bottom diameter Db, a top roundness, a bottom roundness, a concentricity between a top portion and a bottom portion and a surface roughness (Rz) of the through hole VA.

The method for measuring the position accuracy of the through hole VA may include, for example (but not limited to), setting an X-axis parallel to a direction X and a Y-axis parallel to a direction Y in the top view of the substrate SB shown in FIG. 2A, and determining the coordinates of the through hole VA based on the position of the center point of the through hole VA. The method for measuring the top diameter Dt may include obtaining the diameter of the through hole VA from the top view (as shown in FIG. 2A) of the substrate SB along a direction Z, such as obtaining the maximum diameter of the through hole VA at the upper surface SBa of the substrate SB. The method for measuring the bottom diameter Db may include obtaining the diameter of the through hole VA from the bottom view of the substrate SB along the direction opposite to the direction Z, such as obtaining the maximum diameter of the through hole VA at the lower surface SBb of the substrate SB. The method for measuring the waist diameter Dw may include obtaining the minimum diameter of the through hole VA at a depth of 40% to 60% of the through hole VA in direction Z (as shown in FIG. 2B). According to the embodiments of the present disclosure, the direction Z is parallel to a normal direction of the substrate SB, for example, the direction Z may be parallel to a normal direction of the upper surface SBa or the lower surface SBb of the substrate SB, and the direction Z is perpendicular to the direction X and the direction Y, and the direction X is perpendicular to the direction Y, wherein the direction X may be, for example, parallel to a horizontal direction. The method for measuring the top roundness or the bottom roundness of the through hole VA may include, for example (but not limited to), obtaining the minimum width and the maximum width passing through the center of the through hole VA in the above top view or bottom view of the substrate SB, wherein the closer the ratio of the minimum width to the maximum width is to 100%, the more circular the through hole VA is. The method for measuring the concentricity between the top portion and the bottom portion of the through hole VA may include, for example (but is not limited to), obtaining the coordinates of the center of the top portion of the through hole VA as (X1, Y1) and the coordinates of the center of the bottom portion of the through hole VA as (X2, Y2), and calculating the deviation value Dcon between the two centers using the following formula (1):

Dcon=\sqrt{(X1−X2)²+(Y1−Y2)²} (1)

The above deviation value Dcon may be regarded as the concentricity, wherein the smaller the deviation value Dcon, the higher the concentricity. In some embodiments, as shown in FIG. 2A, the first inspection result may further include a first spacing Px, a second spacing Py, and/or a third spacing Pd. The first spacing Px may be the distance between the centers of the two through holes VA that are farthest apart in the direction X. The second spacing Py may be the distance between the centers of the two through holes VA that are farthest apart in the direction Y. The third spacing Pd may be the distance between the centers of the two through holes VA that are farthest apart in the diagonal direction of the substrate SB.

After Step S300, Step S400 may be performed to determine whether a condition of the through hole VA is abnormal based on the first inspection result, that is, to determine whether the condition of the through hole VA is normal or abnormal. The step of determining whether the condition of the through hole VA is abnormal based on the first inspection result (i.e. Step S400) may include comparing the first inspection result with an inspection standard stored in a control device. The control device mentioned in the present disclosure may include, for example, a processing unit, a memory or other suitable devices, which may be used for data processing and comparison, thereby enabling real-time monitoring and feedback. For example, a situation in which the condition of the through hole VA is determined to be normal may include the following: the difference between the position of the through hole VA and the inspection standard is within ±10 micrometers (μm); the difference between the first spacing Px, the second spacing Py, or the third spacing Pd and the inspection standard is within ±10 micrometers; the difference between the top diameter Dt or the bottom diameter Db and the inspection standard is within ±10 micrometers; the top roundness and the bottom roundness are greater than 85%; the ratio of the waist diameter Dw to the top diameter Dt or the bottom diameter Db is greater than 0.6; the concentricity is less than 10 micrometer; and/or the surface roughness (Rz) is less than 2 micrometer, but not limited to the above. When the condition of the through hole VA is determined to be normal in Step S400 (e.g., the condition of the through hole VA of the substrate SB shown in FIG. 9), Step S500 may be performed to perform subsequent steps, such as continuing to form a conductive element (e.g., the conductive element CE shown in FIG. 11) within the through hole VA. When the condition of the through hole VA is determined to be abnormal in Step S400, Step S410 may be performed to perform a through hole rework process on the substrate SB, so as to repair the through hole VA that is in an abnormal condition. For example, as shown in FIG. 2A, when the top diameter Dt of the through hole VA1 is too small, the condition of the through hole VA1 is determined to be abnormal, and the through hole rework process is subsequently performed to repair the through hole VA1.

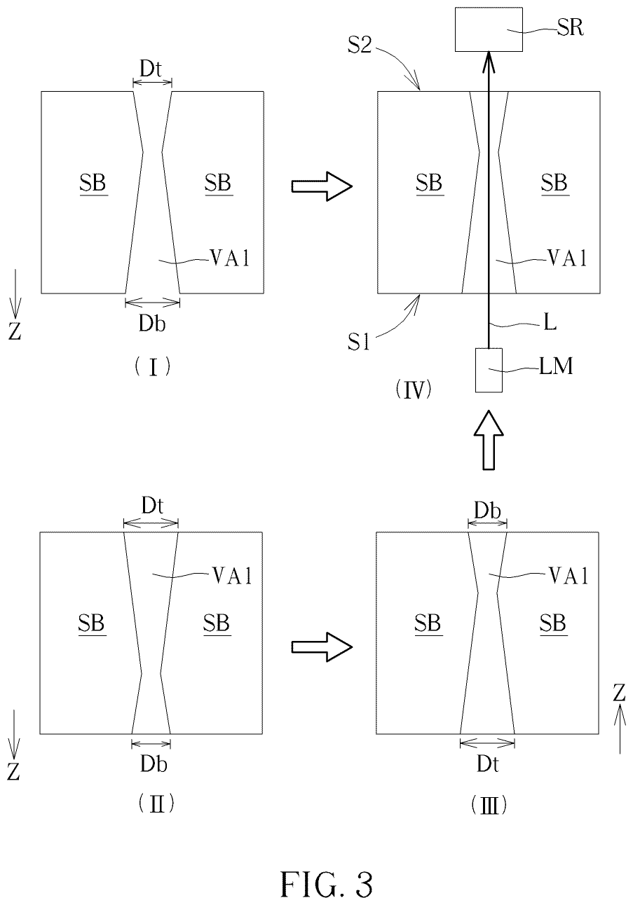

Regarding the through hole rework process of the manufacturing method of the electronic device according to the present disclosure, please refer to FIG. 3 to FIG. 5, and in conjunction with FIG. 1. FIG. 3 to FIG. 5 are schematic diagrams illustrating a portion of the process of a manufacturing method of an electronic device according to an embodiment of the present disclosure. As shown in FIG. 3, the step of performing the through hole rework to repair the abnormal thorough hole VA1 (i.e., Step S410) may include performing a rework direction determining step to determine whether the substrate SB needs to be flipped during performing the through hole rework process. Specifically, the rework direction determining step may include the following steps: As shown in process (I) of FIG. 3, if the top diameter Dt of the through hole VA1 is less than the bottom diameter Db thereof, it is determined not to flip the substrate SB. As shown in process (II) of FIG. 3, if the top diameter Dt of the through hole VA1 is greater than the bottom diameter Db thereof, it is determined to flip the substrate SB, as shown in process (III) of FIG. 3. After performing the rework direction determining step described above, as shown in process (IV) of FIG. 3, a light L may be provided from a light-emitting module LM on a first side S1 of the substrate SB, allowing the light L to pass through the through hole VA1, and a sensor SR is used on a second side S2 of the substrate SB to receive the light L for estimating a position of the through hole VA1, i.e. for locating the position of the through hole VA1, wherein the first side S1 is adjacent to the greater one of the top diameter Dt and the bottom diameter Db, and the second side S2 is opposite to the first side S1. That is to say, the second side S2 is adjacent to the smaller one of the top diameter Dt and the bottom diameter Db. The term “flip” mentioned in the present disclosure means that the element is turned upside down by the flipping step, that is, the top of the element becomes the bottom of the element after the flipping step. The method for performing the flipping may include using a fixture, a robotic arm, any suitable equipment, combinations of the above or any other appropriate method, but not limited herein.

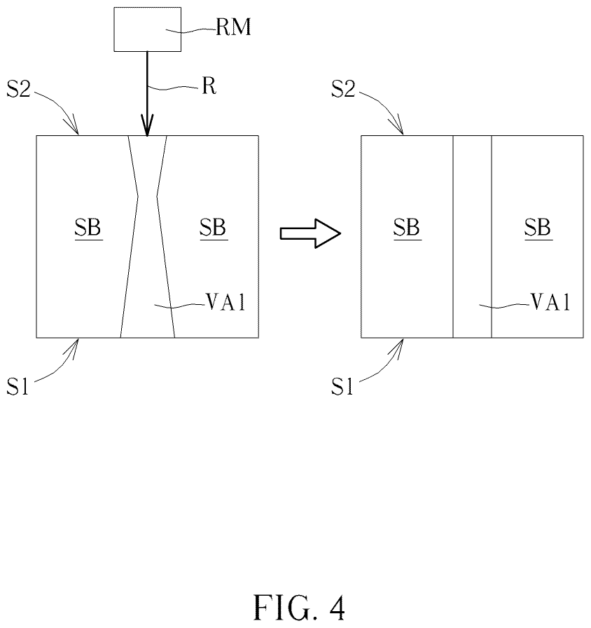

After locating the position of the through hole VA1 through the light L (i.e., as shown in process (IV) of FIG. 3), as shown in FIG. 4, a laser beam R may be provided from a laser module RM on the second side S2 of the substrate SB to enlarge the through hole VA1. For example, the laser beam R may be used to enlarge the smaller one of the top diameter Dt and the bottom diameter Db of the through hole VA1, and may also be used to enlarge the waist diameter Dw of the through hole VA1. In some embodiments, the wavelength of the laser beam R may be less than or equal to 400 nanometers (nm), or less than or equal to 355 nanometers. For example, the through hole VA1 may be directly drilled and enlarged by an ultraviolet (UV) laser, or the through hole VA1 may be ablated by an excimer laser in combination with a barrier layer, a photomask, or a glass build-up layer.

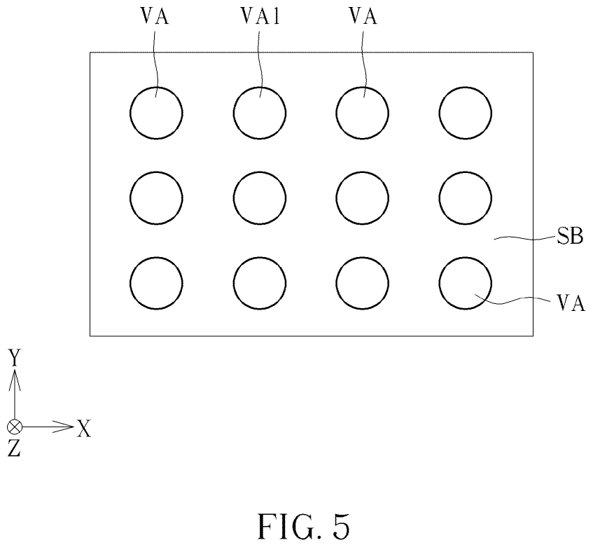

As shown in FIG. 5, a repaired through hole VA1 may be obtained after the through hole VA1 is enlarged, wherein the structural characteristics of the repaired through hole VA1 may be similar to those of other through holes VA that are in the normal condition. According to the manufacturing method of the electronic device in this embodiment, as shown in FIG. 1, after performing the through hole rework process (i.e., Step S410), the method may further include the following steps: After Step S410, Step S420 may be performed to perform a second inspection step to the substrate SB shown in FIG. 5 to obtain a second inspection result, wherein the second inspection result may include at least one of the structural characteristics (as shown in FIG. 2A and FIG. 2B) included in the aforementioned first inspection result, which will not be redundantly described herein. After Step S420, Step S430 may be performed to determine whether the conditions of the through holes VA and the through hole VA1 are normal or abnormal based on the second inspection result. When the conditions of the through holes VA and the through hole VA1 are determined to be normal based on the second inspection result, Step S500 may be performed to perform subsequent steps, such as continuing to form conductive elements (e.g., the conductive element CE shown in FIG. 11) within the through holes VA and the through hole VA1. In some embodiments, when the conditions of the through holes VA and the through hole VA1 are determined to be abnormal based on the second inspection result and confirmed to be irreparable, Step S440 may be performed to scrap the substrate SB.

In some embodiments, as shown in FIG. 1, after performing the first inspection step (i.e., Step 300), the manufacturing method of the electronic device may further include Step S310: providing the first inspection result to the control device. That is to say, the first inspection result obtained through measurement may be fed back to the control device and compared with the inspection standard stored therein, so that the process parameter values for the next substrate SB may be adjusted. For example, the first inspection result and the inspection standard may be substituted into a compensation formula to calculate a compensation parameter value, and by comparing the compensation parameter value with the current process parameter value, the process parameter values for an entire substrate SB or a quarter of the substrate SB during the manufacturing process of the electronic device next time may be automatically adjusted.

According to the manufacturing method of the electronic device of the embodiment shown in FIG. 1, FIG. 2A, FIG. 2B and FIG. 3 to FIG. 5 above, by performing the inspection step during the manufacturing process to determine the condition of the through hole(s) VA, and by reducing abnormalities through the through hole rework process, the production efficiency may be improved, and the yield and reliability of the electronic device may be improved. Furthermore, the through hole rework process includes the rework direction determining step, so that the rework steps for the electronic device may be performed more efficiently during the manufacturing process.

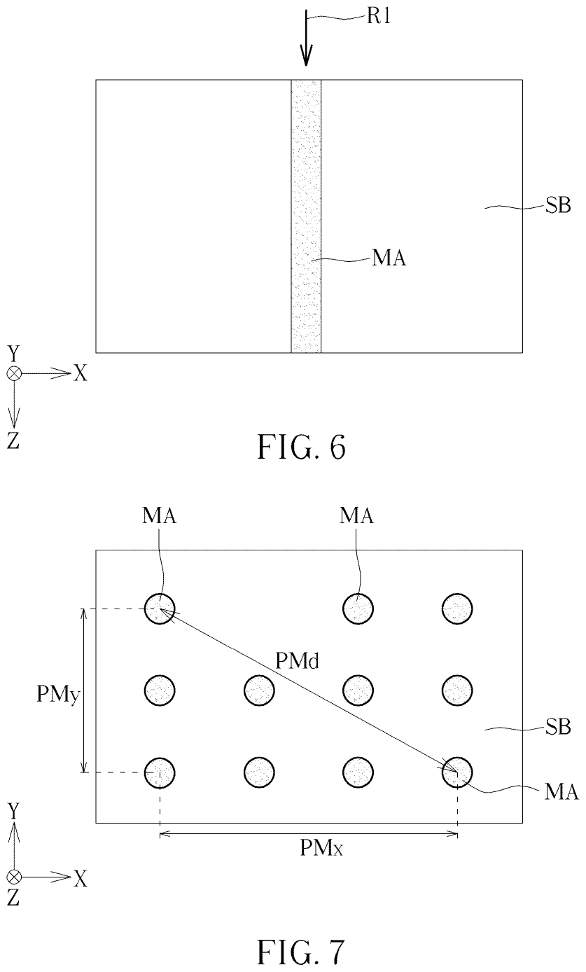

Please refer to FIG. 6 to FIG. 9, and in conjunction with FIG. 1. FIG. 6 to FIG. 9 are schematic diagrams illustrating a portion of the process of a manufacturing method of an electronic device according to an embodiment of the present disclosure. In a manufacturing method of an electronic device according to an embodiment of the present disclosure, the hole-forming process of Step S200 may include the following steps:

Step S210: performing a modification step on a portion of the substrate; and

Step S220: performing an etching step to the portion of the substrate to form the through hole.

In some embodiments, after Step S210 and before S220, the manufacturing method of the electronic device may further optionally include the following steps:

Step S212: performing a third inspection step to obtain a third inspection result; and

Step S214: determining whether a modification condition of the portion of the substrate is normal or abnormal based on the third inspection result, wherein Step S220 is performed when the modification condition of the portion of the substrate is determined to be normal, and a modification rework process is performed on the substrate when the modification condition of the portion of the substrate is determined to be abnormal.

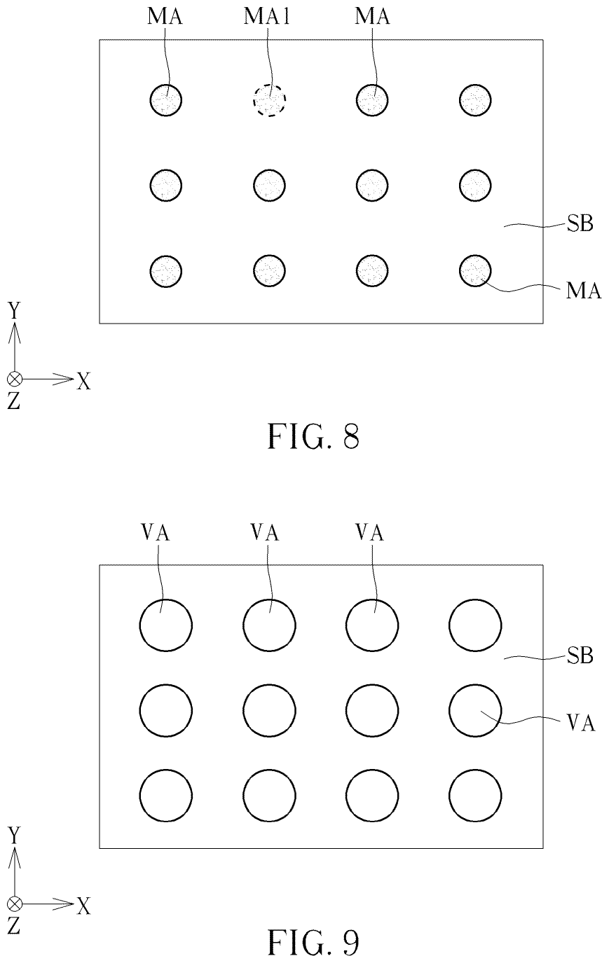

Specifically, as shown in FIG. 6, after providing the substrate SB (i.e., Step S100), Step S210 may be performed to perform a modification step on a portion of the substrate SB. The modification step may, for example, include using a first laser beam R1 to irradiate regions MA of a portion of the substrate SB, such that the crystalline structure of these regions MA is changed, resulting in material modification (represented by a dot-patterned shading in FIG. 6 and subsequent FIG. 7 and FIG. 8). For example, as shown in FIG. 7, the bonding capability of the laser-modified regions MA of the substrate SB is different from that of unmodified regions. In other words, the structure of the laser-modified regions MA may be weakened, or the refractive index of the modified regions MA for light may be different from that of the unmodified regions, so inspection of the modified regions may also be performed based on the difference in refractive index of the regions for light, but not limited herein.

After Step S210, Step S212 may be performed to perform a third inspection step to the substrate SB shown in FIG. 7 to obtain a third inspection result. The third inspection step may include optically inspecting the substrate SB, for example (but not limited to) inspecting by an AOI system. The third inspection result may include the position accuracy of the regions MA, the measurement method thereof may be referred to the measurement method of the position accuracy of the through hole VA mentioned above, which will not be redundantly described herein. In some embodiments, as shown in FIG. 7, the third inspection result may further include a fourth spacing PMx, a fifth spacing PMy, and/or a sixth spacing PMd. The fourth spacing PMx may be the distance between the centers of the two regions MA that are farthest apart in the direction X. The fifth spacing PMy may be the distance between the centers of the two regions MA that are farthest apart in the direction Y. The sixth spacing PMd may be the distance between the centers of the two regions MA that are farthest apart in the diagonal direction of the substrate SB.

After Step S212, Step S214 may be performed to determine whether a modification condition of the modified portion (i.e. the regions MA) of the substrate SB is normal or abnormal based on the third inspection result. The step of determining whether the modification conditions of the regions MA of the substrate SB are normal or abnormal based on the third inspection result (i.e., Step S214) may include comparing the third inspection result with an inspection standard stored in a control device. For example, a situation in which the modification condition of the region MA is determined to be normal may include the following: the difference between the position of the region MA and the inspection standard is within ±10 micrometers; the difference between the fourth spacing PMx, the fifth spacing PMy, or the sixth spacing PMd and the inspection standard is within ±10 micrometers; and/or the regions MA scheduled for modification have all been modified, but not limited to the above. When the modification conditions of the regions MA of the substrate are determined to be abnormal in Step S214, a modification rework process is performed on the substrate SB. For example, if the modified regions MA of the substrate SB shown in FIG. 7 are incomplete or exhibit poor modification quality, the modification rework process may be required for repair. As shown in FIG. 8, the control device may record the coordinates of the position where the region MA is missing in the substrate SB shown in FIG. 7 and record the pulse energy of the first laser beam R1 used during the modification step, and then the modification rework process may be performed to repair the defects or abnormalities, wherein the modification rework process may include using a second laser beam to irradiate a region MA1 of the substrate SB, and one of the pulse energy, the wavelength and the frequency of the first laser beam R1 is different from that of the second laser beam. After performing the modification rework process, the manufacturing method of the electronic device may further include the following steps: performing a fourth inspection step to the substrate SB shown in FIG. 8 to obtain a fourth inspection result, wherein the fourth inspection result may include at least one of the structural characteristics included in the aforementioned third inspection result, which will not be redundantly described herein. After performing the fourth inspection step, it may be determined whether the modification conditions of the modified regions MA and MA1 of the substrate SB are normal or abnormal based on the fourth inspection result. In some embodiments, when the modification conditions of the modified regions MA and MA1 of the substrate SB are determined to be abnormal based on the fourth inspection result and confirmed to be irreparable, the substrate SB may be scrapped.

When the modification conditions of the regions MA of the substrate SB are determined to be normal, or when the modification conditions of the modified regions MA and MA1 of the substrate SB are determined normal based on the fourth inspection result after performing the fourth inspection step, Step S220 may be performed to perform the etching step on the regions MA and MA1 of the substrate SB to form the through holes VA as shown in FIG. 9. The etching step may include a dry etching process or a wet etching process. For example, in the wet etching process, the modified regions MA and MA1 may be etched by an etching solution, and the through holes VA penetrating through the substrate SB may be formed after the etching process is completed.

In some embodiments, after performing the third inspection step (i.e., Step 212), the manufacturing method of the electronic device may further include providing the third inspection result to the control device. That is to say, the third inspection result obtained through measurement may be fed back to the control device and compared with the inspection standard stored therein, so that the process parameter values for the next substrate SB may be adjusted. For example, the third inspection result and the inspection standard may be substituted into a compensation formula to calculate a compensation parameter value, and by comparing the compensation parameter value with the current process parameter value, the process parameter values for an entire substrate SB or a quarter of the substrate SB during the manufacturing process of the electronic device next time may be automatically adjusted.

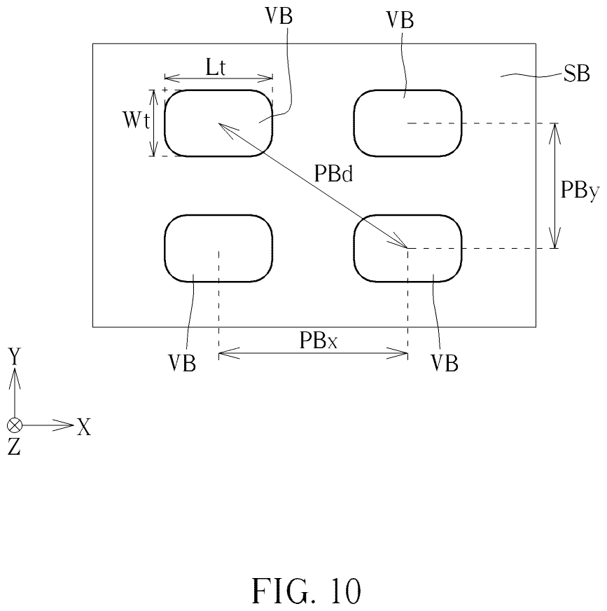

Please refer to FIG. 10, which is a schematic diagram illustrating a portion of the process of a manufacturing method of an electronic device according to another embodiment of the present disclosure. The substrate SB in the embodiment shown in FIG. 10 is different from the embodiment shown in FIG. 9 in that the shape of the formed through holes VB is a rectangle having curved corners. As shown in FIG. 10, in this embodiment, the first inspection result obtained by performing the first inspection step to the substrate SB (i.e., Step S300) may include a position accuracy, a top length Lt, a top width Wt, a bottom length, a bottom width, a top outline shape and a bottom outline shape of the through hole VB. The method for measuring the position accuracy of the through hole VB may include, for example (but not limited to), setting an X-axis parallel to the direction X and a Y-axis parallel to the direction Y in the top view of the substrate SB shown in FIG. 10, and determining the coordinates of the through hole VB based on the position of the geometric center of the through hole VB. The method for measuring the top length Lt and the top width Wt may include obtaining the maximum length in the direction X and the maximum width in the direction Y of the through hole VB respectively from the top view (as shown in FIG. 10) of the substrate SB along a direction Z. The method for measuring the bottom length and the bottom width may include obtaining the maximum length in the direction X and the maximum width in the direction Y of the through hole VB respectively from the bottom view of the substrate SB along the direction opposite to the direction Z. The top outline shape/bottom outline shape may include the outline of the through hole VB obtained from the top view/bottom view of the substrate SB as described above, wherein the outline may, for example, include four curved corners of the through hole VB, but not limited herein. In other embodiments, the shape of the through hole VB may be a rectangle with right angles. In some embodiments, the first inspection result may further include a spacing PBx, a spacing PBy, and a spacing PBd between the geometric centers of the two through holes VB that are farthest apart in the direction X, the direction Y, and diagonal direction, respectively.

Please refer to FIG. 11, which is a cross-sectional schematic diagram of an electronic device according to an embodiment of the present disclosure. The manufacturing process of the through hole VA of the substrate SB in the electronic device ED shown in FIG. 11 may correspond to the manufacturing method of the electronic device shown in the above embodiments. The electronic device ED shown in FIG. 11 is merely an example, and the structure of the electronic device of the present disclosure is not limited herein. As shown in FIG. 11, an electronic device ED includes a substrate SB, a conductive element CE, a circuit structure CST and an electronic unit EU. The substrate SB includes one or more through holes VA. The through hole VA may penetrate through the substrate SB, and the side wall VAS of the through hole VA may be connected to the upper surface SBa of the substrate SB and the lower surface SBb opposite to the upper surface SBa. The substrate SB may consist of a single layer or multiple layers, that is, at least two or more sub-substrates having through holes may be stacked along the direction Z to form the substrate SB, wherein the width, length, thickness, material, thermal expansion coefficient and stiffness of the sub-substrates may be the same or different. The conductive element CE is disposed in the through hole VA, and the circuit structure CST is disposed on a side of the substrate SB and electrically connected to the conductive element CE. The electronic unit EU is disposed on the circuit structure CST and electrically connected to the conductive element CE through the circuit structure CST. Each of the through hole VA has a top diameter Dt and a bottom diameter Db, and a ratio of the top diameter Dt to the bottom diameter Db is greater than or equal to 0.8 and less than or equal to 1.2 (i.e., 0.8≤Dt/Db≤1.2). In some embodiments, a difference between the top diameter Dt and the bottom diameter Db of the through hole VA may range from −15 micrometers to 15 micrometers. In some embodiment, a difference between the top diameter Dt of one through hole VA and the top diameter Dt of another through hole VA may range from −15 micrometers to 15 micrometers, and a difference between the bottom diameter Db of the above through hole VA and the bottom diameter Db of the above another through hole VA may range from −15 micrometers to 15 micrometers. In some embodiments, a mark SBM may further be included inside the substrate SB, but not limited herein.

According to the embodiment shown in FIG. 11, the electronic device ED may further include a buffer layer BL and a seed layer SL. The buffer layer BL may cover the upper surface SBa and the lower surface SBb of the substrate SB and the side wall VAS of the through hole VA, and the seed layer SL may be disposed on the buffer layer BL and disposed between the conductive element CE and the buffer layer BL, wherein the seed layer SL may facilitate the formation of the conductive element CE and/or enhance the adhesion between layers. The circuit structure CST may be disposed on the substrate SB and the conductive element CE, and the circuit structure CST may include one or more conductive layers CL and one or more insulating layers IL, which may serve as a redistribution layer. Each insulating layer IL may have at least one via, so that the conductive element CE may be electrically connected to the conductive layer(s) CL in the direction Z. The conductive layer CL farthest from the substrate SB may include a plurality of connection pads for bonding with the electronic unit EU or other suitable elements. One or more electronic units EU may be disposed on the circuit structure CST and bonded to the circuit structure CST through bonding elements CE1, so that the electronic units EU may be electrically connected to other elements through the conductive layer CL and the conductive elements CE in the through holes VA, for example, further electrically connected to a circuit board CB through bonding elements CE2 disposed on one side of the substrate SB opposite to the circuit structure CST. The conductive element CE and the conductive layer CL may include conductive material, including, for example, copper (Cu), titanium (Ti), aluminum (Al), molybdenum (Mo), nickel (Ni), ruthenium (Ru), tantalum (Ta), tungsten (W), nitride, carbide, other conductive materials or combinations of the above, but not limited herein. The insulating layer IL may include, for example, polyimide (PI), photosensitive polyimide (PSPI), Ajinomoto build-up film (ABF), silicon oxide (SiOx), silicon nitride (SiNx), silicon oxide nitride (SiOxNy) or other suitable dielectric materials, but not limited herein. The bonding elements CE1 and the bonding elements CE2 may, for example, be solder balls and may include tin (Sn), nickel (Ni), gold (Au), copper (Cu), gallium (Ga), other suitable conductive materials or combinations of the above, but not limited herein.

According to the embodiment shown in FIG. 11, the electronic device ED may further include a protective layer PRL surrounding the substrate SB, the circuit structure CST and the electronic unit(s) EU, so as to isolate moisture and air and/or reduce the damage of the electronic unit EU. In some embodiments, a portion of the protective layer PRL located between two adjacent electronic units EU may include a recess RE, but not limited herein. The protective layer PRL may include, organic resin, epoxy, epoxy molding compound (EMC), ceramics, poly(methyl methacrylate) (PMMA), polydimethylsiloxane (PDMS), other suitable materials or combinations of the above materials, but not limited herein. In some embodiments, the electronic device ED may further include a filling layer FL1 and a filling layer FL2. The filling layer FL1 may be disposed between the electronic unit(s) EU and the circuit structure CST to surround and protect the bonding elements CE1, and the filling layer FL2 may be disposed between the substrate SB and the circuit board CB to surround and protect the bonding elements CE2, and may be used as a buffer layer, but not limited herein.

From the above description, according to the manufacturing method of the electronic device and the manufactured electronic device of the embodiments of the present disclosure, by performing the inspection step during the manufacturing process to determine the condition of the through hole, and by reducing abnormalities through the through hole rework process, the production efficiency may be improved, and the yield and reliability of the electronic device may be improved. Furthermore, the through hole rework process includes the rework direction determining step, so that the rework steps for the electronic device may be performed more efficiently during the manufacturing process.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A manufacturing method of an electronic device, comprising:
providing a substrate;
performing a hole-forming process on the substrate to form a through hole in the substrate;
performing a first inspection step to the substrate to obtain a first inspection result; and
determining whether a condition of the through hole is abnormal based on the first inspection result,
wherein a through hole rework process is performed on the substrate when the condition of the through hole is determined to be abnormal, and the through hole rework process comprises performing a rework direction determining step to determine whether the substrate needs to be flipped during performing the through hole rework process.

2. The manufacturing method of the electronic device according to claim 1, wherein the first inspection result comprises a top diameter and a bottom diameter of the through hole, and the rework direction determining step comprises:
determining not to flip the substrate if the top diameter is less than the bottom diameter; and
determining to flip the substrate if the top diameter is greater than the bottom diameter.

3. The manufacturing method of the electronic device according to claim 2, wherein the through hole rework process comprises:
providing a light on a first side of the substrate to pass through the through hole after performing the rework direction determining step, and using a sensor on a second side of the substrate to receive the light for estimating a position of the through hole, wherein the first side is adjacent to a greater one of the top diameter and the bottom diameter, and the second side is opposite to the first side; and
providing a laser beam on the second side of the substrate to enlarge the through hole.

4. The manufacturing method of the electronic device according to claim 3, wherein a wavelength of the laser beam is less than or equal to 400 nanometers.

5. The manufacturing method of the electronic device according to claim 1, wherein the first inspection result comprises at least one of a position accuracy, a top diameter, a waist diameter, a bottom diameter, a top roundness, a bottom roundness, a concentricity between a top portion and a bottom portion, a surface roughness, a top length, a top width, a bottom length, a bottom width, a top outline shape and a bottom outline shape of the through hole.

6. The manufacturing method of the electronic device according to claim 1, wherein the hole-forming process comprises at least one of a laser modification step, a laser drilling step and an etching step.

7. The manufacturing method of the electronic device according to claim 1, wherein the determining whether the condition of the through hole is abnormal based on the first inspection result comprises comparing the first inspection result with an inspection standard stored in a control device.

8. The manufacturing method of the electronic device according to claim 7, further comprising providing the first inspection result to the control device after performing the first inspection step.

9. The manufacturing method of the electronic device according to claim 1, wherein after performing the through hole rework process, the manufacturing method of the electronic device further comprises:
performing a second inspection step to obtain a second inspection result; and
determining whether the condition of the through hole is normal or abnormal based on the second inspection result, and performing subsequent steps when the condition of the through hole is determined to be normal.

10. The manufacturing method of the electronic device according to claim 9, further comprising:
scrapping the substrate when the condition of the through hole is determined to be abnormal based on the second inspection result.

11. The manufacturing method of the electronic device according to claim 1, wherein the hole-forming process comprises:
performing a modification step on a portion of the substrate; and
performing an etching step to the portion of the substrate to form the through hole.

12. The manufacturing method of the electronic device according to claim 11, wherein after performing the modification step and before performing the etching step, the manufacturing method of the electronic device further comprises:
performing a third inspection step to obtain a third inspection result; and
determining whether a modification condition of the portion of the substrate is normal or abnormal based on the third inspection result,
wherein the etching step is performed when the modification condition of the portion of the substrate is determined to be normal, and a modification rework process is performed on the substrate when the modification condition of the portion of the substrate is determined to be abnormal.

13. The manufacturing method of the electronic device according to claim 12, wherein the modification step comprises using a first laser beam, the modification rework process comprises using a second laser beam, and one of a pulse energy, a wavelength and a frequency of the first laser beam is different from that of the second laser beam.

14. The manufacturing method of the electronic device according to claim 12, wherein the determining whether the modification condition of the portion of the substrate is normal or abnormal based on the third inspection result comprises comparing the third inspection result with an inspection standard stored in a control device.

15. The manufacturing method of the electronic device according to claim 14, further comprising providing the third inspection result to the control device after performing the third inspection step.

16. The manufacturing method of the electronic device according to claim 12, wherein after performing the modification rework process, the manufacturing method of the electronic device further comprises:
performing a fourth inspection step to obtain a fourth inspection result; and
determining whether the modification condition of the portion of the substrate is normal or abnormal based on the fourth inspection result, wherein the etching step is performed when the modification condition of the portion of the substrate is determined to be normal.

17. The manufacturing method of the electronic device according to claim 16, further comprising:
scrapping the substrate when the modification condition of the portion of the substrate is determined to be abnormal based on the fourth inspection result.

18. An electronic device, comprising:
a substrate comprising a through hole;
a conductive element disposed in the through hole;
a circuit structure disposed on a side of the substrate; and
an electronic unit disposed on the circuit structure and electrically connected to the conductive element through the circuit structure,
wherein the through hole has a top diameter and a bottom diameter, and a ratio of the top diameter to the bottom diameter is greater than or equal to 0.8 and less than or equal to 1.2.

19. The electronic device according to claim 18, wherein a difference between the top diameter and the bottom diameter ranges from −15 micrometers to 15 micrometers.

20. The electronic device according to claim 18, wherein the substrate further comprises another through hole, a difference between a top diameter of the another through hole and the top diameter of the through hole ranges from −15 micrometers to 15 micrometers, and a difference between a bottom diameter of the another through hole and the bottom diameter of the through hole ranges from −15 micrometers to 15 micrometers.
